(19) United States
(12) Patent Application Publication
(10) Pub. No.: US 2026/0194561 A1
(43) Pub. Date: Jul. 9, 2026

(54) Fiber Optic Current Sensor Module for Switchgear Metering and Field-Testing Applications

(71) Applicant: Adam Jon Zbinden, Kenmore, WA (US)

(72) Inventor: Adam Jon Zbinden, Kenmore, WA (US)

(73) Assignee: OpticAmpere LLC, Spokane, WA (US)

(21) Appl. No.: 19/009,408

(22) Filed: Jan. 3, 2025

(51) Int. Cl. G01R 15/24

(52) U.S. Cl. CPC G01R 15/246; G01R 15/247

(57) ABSTRACT

A fiber optic current sensor (FOCS) installation module for online switchgear metering and portable field testing applications, which mechanically integrates fiber optic current loop sensors with electrical power system conductors to provide online current metering data in low and medium voltage switchgear installations, or for collecting electrical test data, including partial discharge measurements for medium voltage cables and equipment and harmonic current surveys for power quality studies.

### BACKGROUND OF THE INVENTION

Fiber optic current sensors (FOCS) provide a galvanically isolated means for photonically integrating magnetic flux in a closed loop path to optically calculate Ampere's integral based on Faraday rotation of the transmission plane of linearly polarized light:

$$I = \frac{θ}{NV} \qquad Eq . 1$$

Where:
θ=Polarization Rotation Angle Magnitude, expressed as an angular measurement in radians.
N=Number of loops in the fiber optic current sensor magneto-optic transducing loop.
I=Magnitude of Electric Current, expressed in Ampere units of Coulombs/Second.
V=Verdet's constant, expressed in Radians/Tesla, with the photon and magnetic field interaction, and resulting polarization rotation, decreasing with measurement distance from the magnetic field.

Fused silica glass, from which single mode fiber optic cables are drawn from pre-forms, has a Verdet constant of

$$3.6 \frac{rad}{T * m}$$

at a reference wavelength of 633 nm, and where the wave-length dependent Verdet constant at off-reference wavelengths is approximated with:

$$V ( λ ) = V ( {λ}_{0} ) \frac{{λ}_{0}^{2}}{{λ}^{2}} \qquad Eq . 2$$

Where λ₀=633 nm reference wavelength

Interrogating fiber optic current sensors polarimetrically enables the degree of polarization rotation to be measured, thereby enabling the direct calculation of Ampere's integral by photonically transducing the magnetic flux generated by electric current flowing in a conductor being monitored.

US Patent Application 2024/0369601 A1 “Fiber Optic Current Sensor Controller” discloses a polarimetric fiber optic current sensor interrogator which generates deterministic and noise-free measurements of the degree of polarization rotation by measuring the four observable conditions for the Stokes intensity equation using a 1×4 polarization-maintaining pulse splitter with outputs filtered through fiber-optic polarizing filters, and where the analog observable intensity values are converted to digital sampled values where an online programmable logic chipset calculates variations in S1 and S2, which provides information on optical field power transfer between the orthogonally polarized axes for a polarized light pulse, which corresponds to circular birefringence induced by the magnetic field of a conductor and from which polarization rotation angle is calculated, while the variations in S3, relative to S0, transduce changes in linear birefringence caused by mechanical stress such as vibration, which can be observed separately without introducing noise to the polarization rotation measurements necessary for current.

In the preferred embodiment of the present invention, a passive fiber optical polarization filtering module is connected directly with the I/O ports of the fiber optic current sensor module (FOCS), such that the polarization control required for Stokes polarimetry is performed proximate the FOCS module where current is measured, and where the polarization reference optical input to the FOCS module for sensor interrogation is a known linear state (horizontal, linear, or) 45°, and the output of the FOCS sensor is divided through a 1:4 signal splitter, such as a polarization maintaining fused fiber coupler cascade, or a planar light wave silicon bridge splitter chip, where the optical power is divided evenly between four outputs with a monolithic PM transmission axis orientation such that the SOP of the optical pulse is maintained through the 1:4 optical splitter, and where the outputs of said splitter connect to circular polarizers comprised of quarter wave plate fiber optic cable featuring a linear polarizing fiber optic cable with transmission axis fusion spliced at 45 degrees relative to the waveplate fiber, and where a first 3 outputs of the PM splitter are fusion spliced to the circular polarizers, on their 45 degree linear polarizer sides, at rotation angles of 0, 45, and 90, while a fourth circular polarizer fiber optic coil is spliced to the final output of the splitter on the quarter wave plate side of the circular polarizer in parallel, and where the Stokes parameters required for Faraday rotation current calculations are found with Equations 2-5, where the first three intensity measurements are observed with the circular polarizer in circular configuration, where the linear polarizer precedes the waveplate in the optical path and the output is circularly polarized, and where the final intensity measurement is observed with the quarter wave plate preceding the linear polarizer in the photonic circuit, in linear configuration, where the quarter wave plate converts the degenerate circular polarization state which may be present in an elliptically polarized optical pulse back to linear, which creates a filter for measuring the prevalence of right or left circularly polarized light relative to the overall optical intensity which is observed as the sum of horizontal and vertical orthogonal mode intensities for a polarized optical pulse, and where an indoor fiber optic current sensor module not requiring S3 measurements for linear birefringence disturbance compensation, such as environmental temperature or acoustic disturbances, will require the fourth circular polarizer configured in circular configuration with transmission axis rotated 135° relative to the horizontal axis of an input waveguide to further measure the linear Faraday rotation, where circular intensity equations 2-4 reference a right circular polarizer, while a left circular polarizer will measure S1 and S2 in a similar manner at the same angle conditions of 0°, 45°, and 90°, and where a final intensity measurement may alternatively be made in circular configuration at 135°, to fully determine Faraday rotation parameters S1 and S2, in applications where vibration and temperature monitoring with S3 is not required, such as for indoor substations, with Eq. 6:

$${I}_{C} ( 0 ° ) = \frac{1}{2} ( {S}_{0} + {S}_{2} ) \qquad Eq . 3$$

$${I}_{C} ( 45 ° ) = \frac{1}{2} ( {S}_{0} - {S}_{1} ) \qquad Eq . 4$$

$${I}_{C} ( 90 ° ) = \frac{1}{2} ( {S}_{0} - {S}_{2} ) \qquad Eq . 5$$

$${I}_{L} ( 0 ° ) = \frac{1}{2} ( {S}_{0} - {S}_{3} ) \qquad Eq . 6$$

$${I}_{C} ( 135 ° ) = \frac{1}{2} ( {S}_{0} + {S}_{1} ) \qquad Eq . 7$$

The present invention provides a means to integrate a fiber optic loop current sensor into low and medium voltage switchgear, where the required device insulation class is dependent on the system voltage level, by installing a fiber optic current loop sensor concentrically around an electrical conductor, while an alternative embodiment of the present invention teaches a portable lead extender for field surveys which will enable a fiber optic current loop sensor to open in order to be installed around an existing conductor, such as a cable shield ground strap during partial discharge testing of medium voltage cables during very low frequency (VLF) cable testing, where the high frequency coulombic discharges associated with cable insulation partial discharge are measured in the ground strap, and where although the VLF is outputting medium voltage, the ground strap is, by definition, at ground potential, and therefor the lead extender is still a low-voltage device in terms of operating conditions.

### SUMMARY OF THE INVENTION

In an embodiment where the fiber optic current loop sensor is installed permanently in switchgear, the fiber optic loop current sensor is installed in a hermetically sealed, environmentally rated, electrically insulated polymer housing, which features offset bolt mounting holes to secure the fiber optic coil housing to the switchgear interior surface, and the fiber coil is terminated inside the housing at I/O ports, which transmit and receive fiber optic patch cords can mate with, so as to interrogate the fiber optic loop current sensor installed within the housing of the present invention, using the invention disclosed in US Patent Application 2024/0369601 A1.

The mechanical design requirements for the construction of the casing for a fiber optic current loop sensor differ from conventional electromagnetic current transformers, and the present invention provides solutions to the novel design challenges facing fiber optic current sensors installed within switchgear, which also provide advantages for installation:
1) Conventional current transformers consist of wound copper coils with iron cores, and for high ampacity ranges, the amount of copper and iron material required increases accordingly. Therefor weight and form factor scale with ampacity range for conventional electromagnetic current transformers. Whereas for the fiber optic current loop sensor housing module which the present invention discloses, the weight and form factor stays constant across ampacity, as fiber optic current sensors possess infinite bandwidth. Therefor the housing of the module of the present invention, when permanently installed in a switchgear cabinet, occupies a smaller form factor, and embodies less mass, which makes mounting and installation less challenging.
2) While immune to electromagnetic interference, fiber optic cables are sensitive to acoustic disturbances which alter the refractive index of birefringent axes by perturbing the anisotropy of the silicon lattice network of the waveguide, and this is the principle for Rayleigh backscatter readings in optical time domain reflectometry. To avoid this, the sensor housing module of the present invention contains an inner waveguide loose buffer tube micro conduit which guides and insulates the fiber optic loops within the larger interior space of the overall housing. For electromagnetic current transformers vibration does not affect inductive power transfer from which current levels are ratiometrically estimated.

In an alternative embodiment for field surveys of existing conductors which cannot be opened, the present invention provides a stand for a fiber loop current sensor interrogator, which integrated I/O ports which connect to fiber leads which extend through rigid, insulated conduit, at the end of which the fiber cables are broken out to additional I/O ports which interface with a flexible jacketed fiber optic cable which is supported by a force transfer member via support brackets which allows the flexible fiber optic cable to be actuated without placing mechanical stress on the fiber optic loop cable transducer contained within the flexible jacket, and where the action of opening the fiber optic cable jacket and sensor loop using the handle opens one optical port, effectively functioning as a manually operated fiber optical switch, where the end-face connections of the optical I/O terminations can move in parallel or orthogonally to make or break the fiber optic circuit connection in the fiber optic transducer loop.

### DESCRIPTION OF THE FIGURES

FIG. 1 is an embodiment of the invention where a fiber optic current sensor (FOCS) module may be installed permanently in switchgear, where the housing 3 is secured with bolts at mounting holes 1 and I/O ports 2 provide an interface for transmit and receive patch cords with the fiber optic current sensor (FOCS) 4 which is secured within a micro conduit 6 which insulates the fiber optic current sensor (FOCS) 4 from mechanical vibration when it is housed within the module casing 3 and where a cross sectional view of an electrical conductor at a center location relative to 4 is shown with 5. Within the passive fiber optical filter module 8 which is installed proximate the FOCS module, a reference input linear polarizer 9 provides a constant known SOP reference for baseline polarimetry measurements which is monitored at an 80:20 optical coupler 13, while 10 shows the 1:4 optical splitting stage where an optical output from the fiber optic current sensor 4 is divided equally across four polarization maintaining output fiber optic channels with monolithic birefringent transmission axes via polarization filtering module ports 22, which connect in line at fusion splice locations, with splice angles as shown, to circular polarizers 11 which are comprised of linearly birefringent fiber optic elements tuned to produce quarter wave phase retardance which are fusion spliced to a linear polarizing fiber optic element with transmission axis aligned at 45° with respect to the quarter wave retarder fast and slow birefringent transmission axes, where the first 3 outputs of 10 are fusion spliced to 11 in circular configuration at angles of 0°, 45°, and 90° respectively, while a 4^{th} output of 10 is fusion spliced to the circular polarizer 11 in linear configuration as shown, and where the I/O ports 12 and 22 of the passive fiber optical filtering module 8 optically connect the I/O ports 2 of the FOCS module with a remote transceiver interrogator which also incorporates online reference power level feedback monitoring with 80:20 optical coupler stage 13.

FIG. 2 depicts a side view of the switchgear mounted fiber optic current sensor module, where the inner wave guide micro-conduit shown with 6 routes the fiber optic current sensing waveguide transducer 4 within the larger device housing 3 around an electrical conductor 5, while fiber optical cable sensor micro-conduit 6 is supported and insulated within the FOCS device housing 3 with vibration damping support columns shown with 7, with device mounting location 1 depicting a bolted, vibration damped connection to a switchgear cubicle mounting location, where the optical I/O ports 2 terminate the fiber optic current sensor cable 4 to provide a direct I/O interface for the switchgear mounted FOCS module of the present invention with external optical networks, and an input fiber optic polarizer coil is shown providing a reference input within passive fiber optic polarization filtering module 8 while the output of the FOCS transducer cable 4 is divided into four pulses which are filtered through polarizing fiber optic elements before routing to the I/O ports 12 of the passive fiber optic polarization filter module 8 which interfaces directly with the I/O ports 2 of the fiber optic cable sensor housing module of the present invention via polarization filtering module I/O ports 22.

FIG. 3 depicts an isometric view of the present invention, where three sub-modules housing the fiber optic current sensor cable transducer, passive in line fiber optic polarization filters, and electro-optical transceivers, respectively, allows for a distributed network for increased installation flexibility, and where the sub-modules are networked with fiber optic patch-cords, and installing the in-line fiber optic polarization filters proximate the fiber optic current sensor cable is the preferred embodiment, and where the opto-electronic transceiver sub-module 14 is powered by a battery pack 19 with linear voltage regulator 20 which energizes single-mode optical transmitter 21 and photo-diode array 16 which transmits analog voltage outputs to single-ended A/D conversion inputs of digital signal processing chip 17 with a digital output for networking or display shown with 18.

FIG. 4 depicts the field testing embodiment of the present invention where a lead-extending, manually switchable fiber optic current loop sensor housing provides means to open a flexibly jacketed fiber optic loop transducer in order to install the fiber optic loop sensor necessary for polarimetric fiber optic current sensing in a field survey setting where a conductor cannot be broken, where 1 provides a mounting location for a portable fiber optic current sensor interrogator unit, such as taught in US Patent Application 2024/0369601 A1, with I/O ports interfacing at 2 to connect with interior patch cord fiber optic wave guides 17 connecting with a fiber optic current sensor cable transducer 11 via a 3-port fiber optic circulator 19 and installed within rigid insulated conduit 3 which is connected to a device actuation and support brace shown with 18, which provides means to open the fiber optic loop sensor 11 by actuating the handle 4 which can transfer force in tension and compression via an inelastic and incompressible force linkage shown with 8 which holds the outer flexible protective fiber cable jacket 14 of the fiber optic loop sensor 11 using intermediate support brackets shown with 7 and where the incompressible and inelastic mechanical linkage element 8 is connected to the device overall support brace 18 at an initial mounting bracket shown with 15, which integrates an interlocking key mechanism 10 which mates with interlocking key mechanism 16 at an end point of the fiber optic cable sensor jacket 14, where the fiber optic cable sensor 11 is terminated with an optically reflective mirror end-face 12 within cable jacket 14 to double the Faraday rotation measured, and where the handle 4 transfers force to the terminal fiber cable support bracket 9 via incompressible, inelastic linkage 8 via a rotatable bearing mechanism shown at 6 at a top location of the overall device support brace 18 using intermediate linkages as necessary to provide required degrees of freedom for actuation of the fiber optic cable switch comprised of keyed latching mechanism 10, 16 which switches an optical I/O sensor connection 12 at an end location of the fiber optic cable jacket 14.

FIG. 5 depicts the field testing embodiment of the present invention when the handle 4 has opened the fiber optic current sensor transducer cable 11 by unlatching 10 and 16 using force transfer to a terminal fiber cable support bracket 9 which moves the terminated fiber optic sensor reflective mirror end face 12 within the fiber optic cable jacket 14 into a mechanically open state where a conductor can be installed concentric to 14.

### DETAILED DESCRIPTION OF THE INVENTION

While the exterior housings of the device provide environmental protection for the internal fiber optic waveguide components, all fiber optic waveguides, whether sensing or patch cord, require a secondary, interior micro-conduit of loose buffer tube style mechanical protection, such as used in outside plant cable, in addition to protective jacketing, such that the influence of environmental mechanical vibrations is minimized.

The overall module housing of the device, regardless of disclosed embodiment, shall be comprised of non-conducting, electrically insulated polymers, and this will be obvious to one skilled in the art field of the present invention. The fiber optic current sensor loop transducer cable shall be single mode fiber (SMF) throughout the circuit, and this will also be obvious to one skilled in the art. The optical I/O ports which comprise the manual switch at latching mechanisms 10,16 shall be of durability to withstand long term mechanical cycling.

For field surveys, it will be obvious to one skilled in the art that a stand may be useful to support the measurement circuit off the ground when measuring flux around a conductor. For a partial discharge test environment, the ground conductor where high frequency coulombic discharges are occurring is at, by definition, earth ground voltage potential, and so the device may be classified as low-voltage in the partial discharge test environment when considering electrical insulation requirements and construction material requirements for the present invention. For measuring current at higher operating voltages using the present invention, it will be obvious to one skilled in the art that dielectric insulation requirements for the fiber optic coil sensor module housing will increase accordingly and materials and methods for insulating fiber optic waveguides and their housing modules in the presence of electric fields will be selected accordingly from the existing art.

It will be obvious to one skilled in the art that all fiber lead patch cords shall be polarization maintaining such that all connector interfaces have fiber terminations where fast and slow birefringent polarization axes remain aligned for coupled launches at fiber optical port connection interfaces.

The disclosure of 2024/0369601 A1 enables a module of passive in-line fiber optical polarization filters, with transmission axis offset relative to the monolithic polarization maintaining axes of 1×4 fiber optic coupler outputs with fusion splicing, such that permanent inline polarization filtering for the Stokes intensity equation, as well as secondary linear polarization filtering for the polarization reference input, occurs directly at the I/O interface of the present invention by connecting the module of passive fiber optic polarization filter coils proximate the housing of the present invention via short patch cords or alternate methods. This enables optical power measurement variations corresponding to current data to be sent over long distance to a remote optoelectronic receiver which interrogates the present invention, and where the transmitted Stokes intensity variables, being calculated proximate the output of the fiber optic coil current sensor housed within the present invention, can be transmitted with known polarization output states with deterministic polarization dependent loss such that the state of polarization (SOP) measurement variable which current depends on according to Eq. 1 is not subject to signal degradation over transmission links and remains noise-immune over long haul data transmission.

For U.S. Pat. No. 11,175,315, Crossarm insulator pin auxiliary mounted passive all fiber electro optical current sensor, this enables accurate remote interrogation of a power line sensor over multi-mile line lengths, as required given the data transmission distance between remote substations or pole mounted reclosers, where optoelectronic transceiver interrogator modules such as 2024/0369601 A1 are installed and the passive and remote pole-mounted fiber optic current sensor of 11,175,315.

In a first embodiment of the present invention where the polarization filtering occurs in a module proximate the I/O ports of the fiber optic current sensor cable transducer, the back-plane of the SCADA concentrator may accept more I/O within a constant form factor, such that only an array of fiber optic links are required to network a single remote fiber optic current sensor (FOCS) of the present invention into a relay backplane, where digitally sampled optical power measurement values correspond to the Stokes intensity observables which contain polarimetry data corresponding to the magnetic field strength within the electrical conductor corresponding to current, based on the degree of rotation, as observed from changes in magnitude to S1 and S2 relative to S0, where observations of S3 relative to S0 contain a separate channel of information relating to the linear birefringence and degree of phase delay of an optical pulse, corresponding to temperature and vibration.

In the indoor switchgear fiber optic current sensing application of the present invention, the environments where the fiber optic current sensors are installed are both climate controlled and externally monitored for temperature, such that no hardware provisions for temperature sensing or intrinsic temperature compensation are required for robust device accuracy. In the case of the outdoor NETA partial discharge and power quality ammeter application, an operator will have access to temperature data for online compensation using a laboratory derived compensation curve.

As the effect of temperature alters the performance of fiber optical transmission by altering the crystalline lattice anisotropy of the silicon waveguide material, thereby changing the birefringence and refractive indices of the slow and fast transmission axes, it is hypothesized that a signature phase shift as observed from S3 relative to S0 will be observed at the interrogator of 2024/0369601 A1 which will accurately transduce the ambient temperature, though this is not required, as the claimed applications of the present invention relate to indoor, climate controlled and monitored environments, or outdoor test-operator-supervised environments, where temperature is not a random variable introducing noise to the measurement process as it can be measured and accounted for in the output calculations of the digital signal processing programmable logic controller chipset which converts the DC-modulated and filtered analog voltage outputs of a photo-detecting module into sampled values for data visualization and analytics.

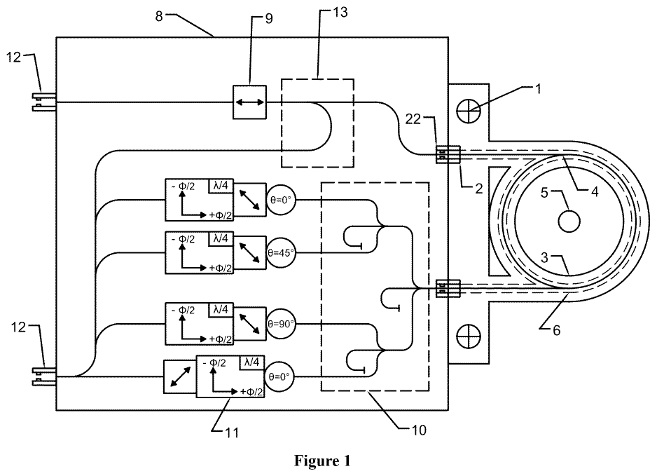

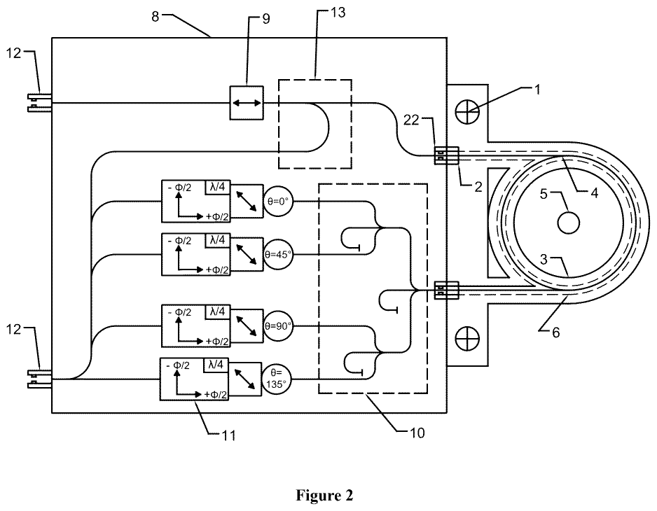

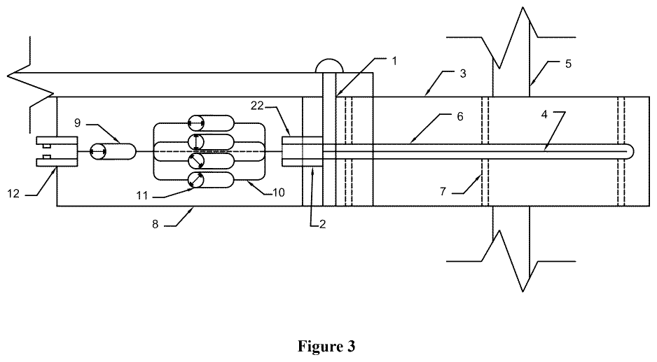

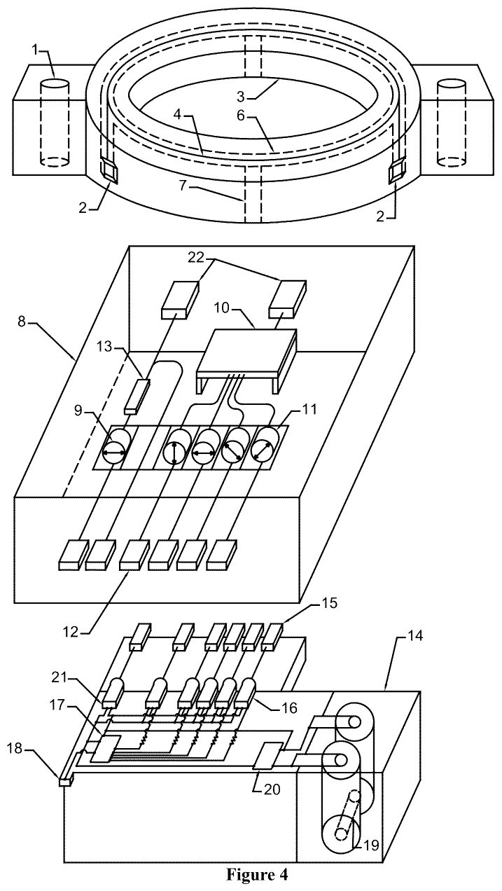

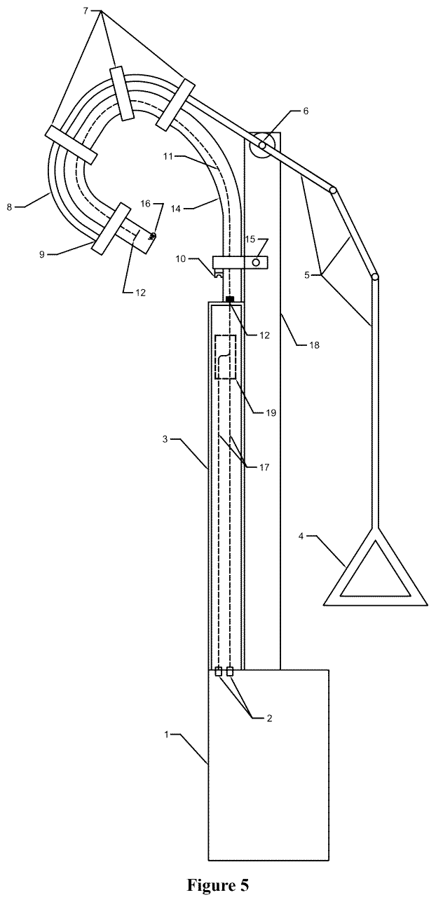

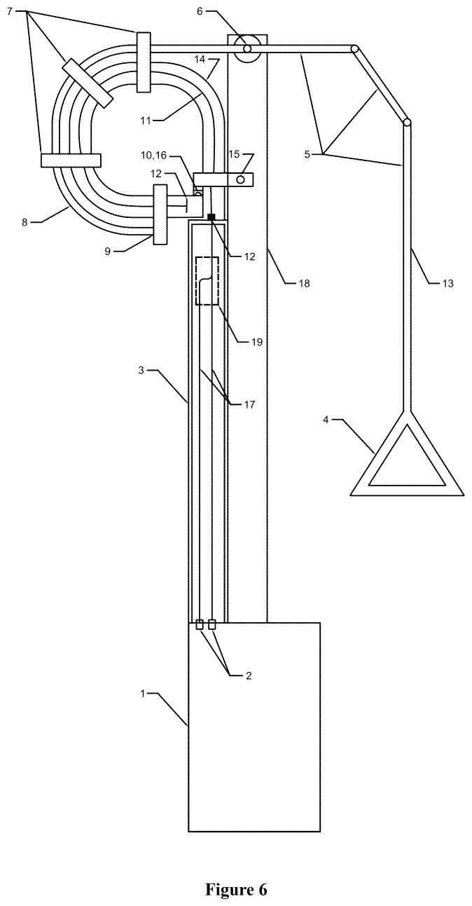

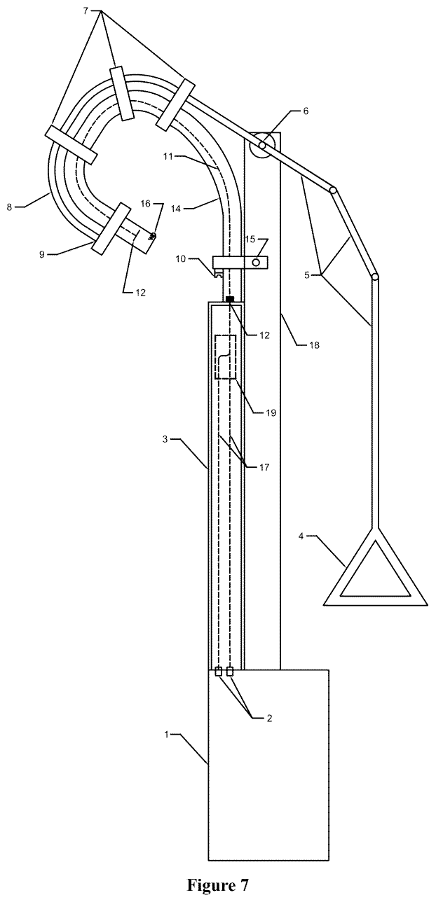

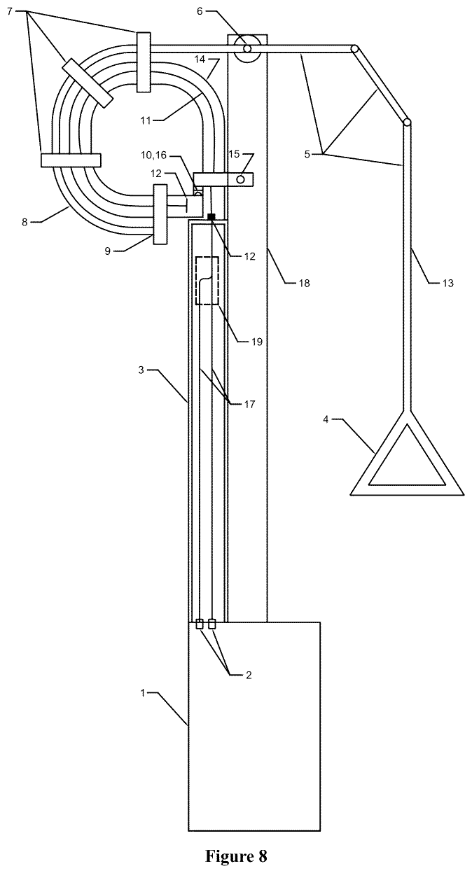

Packaging the optical filtering components of 2024/0369601 A1 into a module of passive fiber optical polarization filters and polarization maintaining star couplers allows the photonic calculations to occur proximate the switchgear installed FOCS module of FIG. 1, FIG. 2, FIG. 3 and FIG. 4, such that the input port of the present invention has a linear polarizer directly connected through input port 2, and the output port of the present invention 2 connects to a polarization maintaining 1:4 fiber-coupled planar light wave silicon bridge splitter chip, with outputs connected to in-line fiber optic polarizers connected via extinction-ratio calibrated fusion splices at precise transmission axis.

A second embodiment of the present invention will also include insulated low impedance test shunt jumper cables adapted to connect between a high voltage equipment bushing tap, and ground grid nodes, with a fiber optical current sensor transducer cable adapted to be permanently connected around said electrical shunt jumper cable for the detection of the magnetic fields associated with the charge flow to ground from the insulator bushing due to breakdown in distributed capacitance within the high voltage dielectric insulation.

It will be obvious to one skilled in the art that the switchable FOCS configuration of the third embodiment of the present invention which is taught for attaching the FOCS around unbroken ground cables may be adapted, using suitable all dielectric insulation materials with anti-tracking carbon compounds as required for installing dielectric fiber optic cable circuits in high voltage environments, to be installed with hot sticks around high voltage conductors.

While it is sufficient to perform one closed loop optical integration path of magneto-optical sensing in the present invention for the accurate derivation of current from the observed polarization rotation, it will be obvious that terminating the fiber optic cable sensor (FOCS) transducer cable, where polarization rotation in the presence of a central magnetic field occurs, in a lossless reflective mirror, such that polarized photons are reversed at the end of the loop, adds another flux integration on the return circuit to the input of the FOCS transducer cable, where the rotated polarized photons branch at 3-port fiber optic circulator 19 to a receiver link of 17 which links to a photodetector channel for polarization rotation derived current calculations.

The procedure for tuning the splice angles of the polarizing filters relative to the star coupler polarization maintaining fiber axes for Stokes intensity measurements is comprised of the following steps:
1) Tuning single mode fiber to a quarter wave delay of induced linear birefringence, resulting from a ¼-wave equivalent bend radius on a mandrel wrap, approximates the case of a rotating quarter wave plate, for any axis orientation with respect to a linearly +45° polarized reference signal followed by a quarter wave plate applied to the input as a right circular polarized (RCP) reference calibration signal. Attach the output of the quarter-waveplate fiber coil being tuned to a polarimeter with observable polarization sphere graph capabilities, where:

$$2 α = {cos}^{- 1} ( \frac{{S}_{1}}{{S}_{0}} )$$

plots the polar rotation angle, on the observable polarization sphere, from the positive S1 axis, in spherical coordinates.

$$δ = {tan}^{- 1} ( \frac{{S}_{3}}{{S}_{2}} )$$

plots the polar phase delay, on the observable polarization sphere, from the positive S2 axis, in spherical coordinates.
   Connect a depolarized optical reference light source to a 45 degree rotatable linear polarizer reference module followed by a quarter wave plate to generate a right circular polarized (RCP) polarization optical reference signal, and transmit through the single mode fiber optic cable which is being tuned for π/2 phase retardance based on refractive index differences between the horizontal and vertical birefringent axes of the single mode fiber coil, and adjust the bend radius until the quarter wave plate output state of polarization evolves completely from a right circular polarized (as transmitted from the reference source) to a +45° linear state of polarization or left circular polarized SOP, or to any point on the figure-8 which is traced between the states of +45, RCP, and LCP on the OPS during a phase rotation of a quarter wave plate, where the Stokes vector of the output of the quarter wave plate fiber cable when it is rotated at any angle with respect to the reference calibration input of right circular polarization is described with:

$${S}^{′} = ( \begin{matrix}1 \\ sin ( 2 θ ) \\ - cos ( 2 θ ) \\ 0\end{matrix} ) \qquad Eq . 8$$

Where the output of Eq. 8, over a range of π, or 180°, yields a FIG. 8 on the observable polarization sphere corresponding to transitions between linear +45°, RCP, and LCP. The quarter wave retarding fiber bend radius can be tuned to precise levels of linear birefringence by monitoring the output on the observable polarization sphere, while adjusting the bend radius to filter the state of polarization of the reference input to a point on the OPS figure-8 which equals the output of a rotating quarter waveplate, for any arbitrary alignment angle of the quarter waveplate fast and slow axes with respect to the right circular polarized optical calibration reference signal, based on the Mueller matrix of Eq. 8 as applied to the unit-normalized Stokes parameters of the RCP optical reference input:

$${S}_{ref} = [ \begin{matrix}1 \\ 0 \\ 0 \\ 1\end{matrix} ] \qquad Eq . 9$$

An initial starting radius and overall length of fiber coil for iterative tuning in the manner described above is calculated by first finding the birefringence, or difference in refractive indices between the orthogonal axes, associated with a-beat length of the single mode fiber waveguide:

$${L}_{B \frac{π}{2}} = \frac{1}{4} ( \frac{λ}{β} ) = \frac{1}{4} ( \frac{2 π}{( \frac{2 π}{λ} ) \vert {n}_{x} - {n}_{y} \vert} ) \qquad Eq . 10$$

Where the phase birefringence β=|nₓ−n_{y}|, the absolute value of the difference in refractive indices between the orthogonal birefringent axes of the wave plate fiber coil, where the slow axis of the fiber optic wave plate is perpendicular to the coil plane and experiences an increase in effective refractive index proportional to applied bend radius and the fast axis is parallel to the plane of the coil, and experiences a decrease in effective refractive index with applied bend radius, and λ is the center wavelength of the optical light source, and where the bend radius of the coiled single mode fiber which is being tuned to produce quarter wave phase retardance is calculated based on the refractive index difference, or magnitude of linear birefringence, required to equal the quarter wave beat length and phase birefringence found with Eq. 10 as:

$${n}_{\frac{π}{2}} = {n}_{x} - {n}_{y} = \frac{EC ( \frac{{r}^{2}}{{R}^{2}} )}{2} \qquad Eq . 11$$

### Where:

r=fiber optic waveguide radius
R=bend radius of fiber optic cable
E=Young's modulus of fiber optic cable (7.5*10¹⁰ Pa for fused silica waveguides)
C=Stress-optic coefficient of fiber optic cable (3.28*10⁻¹² Pa⁻¹ for fused silica waveguides)

Tuning circular polarizers comprised of quarter wave delay fiber cable tuned in Step 1 combined with fiber optic linear polarizers spliced at +45° or −45° with respect to the fast and slow axes of the quarter wave plate fiber optic cable. With PM-aligning fusion splicer, rotate quarter wave plate fiber cable axes, as tuned in Step 1, with respect to a linear fiber polarizer which is connected at arbitrary angle to depolarized optical reference source, with the output of the QWP fiber coil connected to a polarimeter, until RCP or LCP polarization states are obtained on the observable polarization sphere connected to the output of the quarter wave plate fiber cable, where the required splice angle for calibrating and manufacturing a circular polarizing filter is obtained. Alternatively inject an RCP polarization reference signal, generated by transmitting depolarized light through a linear +45° polarizer followed by a calibrated reference quarter wave plate, into a stationary quarter wave retarding fiber coil, and with PM-aligning precision fusion splicer, rotate the fiber optic linear polarizer transmission axis with respect to the fast and slow axes of the quarter wave delay fiber tuned in Step 1 until a null intensity extinction ratio is measured on a photodetector connected to the output of the fiber optic linear polarizer.

Steps 1 and 2 create the circular polarizing filter characteristics which then may be used in circular configuration (linear polarizer→QWP) to measure Stokes parameters S1 and S2 or in linear configuration (QWP→linear polarizer) to measure S3.
1) To configure S3 measurement channels on the PM-fiber star coupler outputs: connect a depolarized light source as an input to a 45 degree rotatable linear polarizer reference module followed by a reference quarter wave plate, to generate an RCP reference signal to the input of a 1×4 PM star coupler. At a PM 1×4 channel output fiber, rotate the circular polarizer tuned from Step 2 in linear configuration, where the quarter wave plate fiber end of the circular polarizer is spliced to the PM star coupler fiber output axes, until null intensity extinction ratio is measured on a photodetector connected to the output of the circular polarizer, where the RCP generator reference signal is completely rejected by the circular polarizing filter operating in linear configuration, at the required splicing angle to measure S3.
2) Configure S1 and S2 measurement channels: at a PM 1×4 channel output fiber, rotate a circular polarizer tuned from Step 2 in circular configuration, where the linear polarizer fiber end of the circular polarizing filter is spliced to the PM-axes of the star coupler fiber outputs, until null extinction ratio for the polarization state which the filter is tuned to reject is measured on a photodetector connected to the output of the circular polarizer, based on the Mueller matrix for the polarizing filter, using corresponding polarization reference inputs generated by the calibrated precision rotatable linear polarizer and quarter wave plate reference generator modules.
3) Verify tuning of all polarization filtering output channels after splicing by measuring raw filtering characteristics of circular polarizing filters with respect to a depolarized optical reference input to the 1×4 PM star coupler on the observable polarization sphere with the attached polarimeter. Outputs should be polarized according to the output Stokes parameters obtained from the Mueller matrices of the polarizing filters.

1. A fiber optic current sensor (FOCS) module, which provides a complete magneto-optical flux integration path around an electrical conductor, comprising:
An electrically insulated and non-conductive fiber optic current sensor module, featuring an integrated mounting and support section with bolt holes for mounting said module in a switchgear cabinet interior surface, where a mechanically integrated interior micro conduit with vibration dampening supports insulates a fiber optic current sensor cable routed within said fiber optic current sensor module, and where said interior fiber optic cable is terminated at input and output ports on said mounting and support location of said fiber optic current sensor module which interface with a proximate fiber optic polarization filtering module, which contains a linear polarizer which filters an optical input to said fiber optic current sensor module, and a polarization maintaining optical coupler which divides an output of said fiber optic current sensor module at four polarization maintaining fiber optic outputs where each of said outputs is fusion spliced to fiber optic circular polarizers comprising a linearly birefringent fiber optic cable tuned to produce quarter wave phase retardance fusion spliced to a linearly polarizing fiber optic cable with transmission axis aligned at 45° relative to the fast and slow axes of the quarter wave phase delay producing fiber optic cable of said circular polarizer, where a first 3 of said circular polarizers are spliced in circular configuration at offset angles of 0°, 45°, and 90° to the polarization maintaining outputs of the 1:4 fiber coupler, while a fourth circular polarizer is fusion spliced in linear configuration to the fourth fiber coupler output and where interrogation of the S3 channel monitors perturbations to sensor network linear birefringence which transduces environmental factors including vibration and temperature, and where an opto-electronic transceiver module is comprised of a battery source with linear voltage regulator which provides electrical power for a single mode optical transmitter and a photo-diode array which transmits analog voltage outputs to a digital signal processor chip with integrated analog to digital conversion inputs and where said digital signal processor chip has outputs for display or networking.

2. A lead-extending, manually switchable fiber optic current sensor (FOCS) field testing module, which provides a complete magneto-optical flux integration path around an electrical conductor in a field environment, comprising:
A docking location for a fiber optic current sensor interrogator, with input and output ports at a top location of said docking location connecting with a set of duplexed fiber optic transmission cables housed within insulating conduit and connecting via a 3-port fiber optic circulator with a fiber optic current sensor transducer cable housed within a flexible protective jacket, and where a support brace is connected in parallel to said conduit, and integrates an incompressible and inelastic mechanical force linkage between said fiber optic cable sensor, and a handle, using a plurality of fiber optic cable jacket support brackets connected to said mechanical linkage, and where the fiber optic cable sensor housed within the protective jacket which is supported by said brackets is terminated at a lossless reflective optical mirror at an end point location of said fiber optic current sensor cable insulated within said fiber cable jacket, after a location on said device where a final fiber sensor cable jacket support bracket terminates said mechanical linkage, and where said end point features a moveable keyed latching mechanism which connects with a stationary keyed latching mechanism located on an initial fiber optic cable support bracket located on the support brace of the device, and where the handle can switch an optical port on the fiber optic current sensor cable between open and closed states, via its terminated reflective mirror end face connection located on the fiber optic cable sensor jacket, using a rotatable bearing mechanism located at a topmost location of the support brace, and where a plurality of intermediate mechanical linkages between said handle, and said inelastic and incompressible mechanical linkage which actuates the fiber optic switch via the support brackets, provides additional degrees of freedom for actuation.
